(19) United States
(12) Patent Application Publication
(10) Pub. No.: US 2008/0010574 A1
(43) Pub. Date: Jan. 10, 2008

(54) INTEGRATED CIRCUIT ARRANGEMENT AND METHOD FOR OPERATING AN INTEGRATED CIRCUIT ARRANGEMENT

(75) Inventors: Marcus Janke, Munich (DE); Peter Laackmann, Munich (DE)

Correspondence Address: DICKSTEIN SHAPIRO LLP, 1177 AVENUE OF THE AMERICAS 6TH AVENUE, NEW YORK, NY, 10036-2714, US

(73) Assignee: INFINEON TECHNOLOGIES AG, Neubiberg (DE)

(21) Appl. No.: 11/763,140

(22) Filed: Jun. 14, 2007

(30) Foreign Application Priority Data
Jun. 14, 2006 (DE) 10 2006 027 682.5

(51) Int. Cl. G01R 31/28

(52) U.S. Cl. 714/731

(57) ABSTRACT

An integrated circuit arrangement having a test line, a test signal generator which is coupled to the test line and is designed to pass a test signal onto the test line, and a comparison unit inclduing an input for applying a clock signal, the comparison unit being coupled to the test line and being designed to detect a propagation time of the test signal over the test line and to check whether the clock signal and the propagation time are in a predefined relationship.

### CROSS-REFERENCE TO RELATED APPLICATION

This application claims priority to German Patent Application Serial No. 102006027682.5, which as filed Jun. 14, 2006, and is incorporated herein by reference in its entirety. cl FIELD OF THE INVENTION

The invention relates to an integrated circuit arrangement for checking the frequency of a clock signal and to a method for operating such a circuit arrangement.

### BACKGROUND

Circuit-internal clock signal generation is often provided in microcontrollers for security-relevant applications. Alternatively, an external clock signal can also be applied to interfaces provided for this purpose in order to operate the corresponding chip. An external clock signal is also used, for example, to communicate with the chip.

Internal clock signal generation makes it possible to operate the chip at high frequencies even if the externally applied (for example for communication) clock frequency is lower.

Furthermore, internal clock signal generation protects against an attack. On the one hand, it is difficult to synchronize applied signals for the purpose of the attack in a circuit arrangement having internal clock signal generation. On the other hand, it is not readily possible to reduce the internal clock during the attack.

In a circuit arrangement having internal clock signal generation, the following procedure may be used to test the clock frequency of the internal clock signal: the clock frequency is detected by means of a comparison using two frequency sensors. One frequency sensor detects a lower cut-off frequency and the other frequency sensor detects an upper cut-off frequency. The disadvantage of this arrangement is that both frequency sensors may be the target of an attack. Another disadvantage is that the frequency sensors are also associated with a correspondingly higher power consumption of the circuit.

Another approach for checking the internal clock involves comparing the latter with an external clock. A register is provided for this purpose. However, such an arrangement does not protect against an attack in which the frequency of the external clock is reduced, which is possible. This is because the frequency of the internal clock is also reduced thereby.

### BRIEF DESCRIPTION OF THE DRAWINGS

FIG. 1 shows a schematic circuit diagram of a first exemplary embodiment of an integrated circuit arrangement.

FIG. 2 shows signal profiles of signals within the circuit arrangement.

FIG. 3 shows a schematic circuit diagram of a second exemplary embodiment of an integrated circuit arrangement.

### DETAILED DESCRIPTION

One exemplary embodiment of an integrated circuit arrangement comprises a test line and a test signal generator which is coupled to the test line and is designed to pass a test signal onto the test line. The circuit arrangement also comprises a comparison unit having an input for applying a clock signal, the comparison unit being coupled to the test line and being designed to detect a propagation time of the test signal over the test line and to check whether the clock signal and the propagation time are in a predefined relationship.

The circuit arrangement makes it possible to check the clock frequency in a reliable manner.

The predefined relationship, for example a propagation time which the signal shall require over the test line, is provided by a storage means in one exemplary embodiment. In one exemplary embodiment, the comparison unit is provided with said relationship via an input.

In one exemplary embodiment, a reference signal for comparison with the clock signal is generated in a part of the circuit arrangement which is independent of clock signal generation. In this case, the propagation time of the test signal over the test line is used as a reference. This approach is based on the very stable propagation time over the test line, which propagation time is independent of the function of the circuit. The propagation time depends on the length of the test line.

In one exemplary embodiment, the circuit arrangement detects whether the propagation time of the signal over the test line is at least a predefined first multiple of the clock duration of the clock signal and is at most a predefined second multiple of the clock duration of the clock signal. It is also conceivable for the minimum value and maximum value to coincide. As the length of the line increases, the relative error caused by mismatch of the line or measurement errors is reduced.

In one exemplary embodiment, the comparison unit comprises a counter whose opening time is controlled by the propagation time of the signal. During the opening time, clock pulses of the clock signal applied to the input of the comparison unit are counted, that is to say the clock pulses are counted while the test signal runs over the test line. This enables a comparison in which the number of clock pulses counted is compared with a predefined comparison value or a comparison value range.

In one exemplary embodiment, the test line is arranged such that it runs back and forth or in meandering fashion in order to arrange the requisite length of the test line in a limited space.

In one exemplary embodiment, the test line is arranged in an upper layer of the integrated circuit arrangement. In this manner, the test line covers the rest of the circuit arrangement lying underneath it and prevents visual spying attacks on its method of operation. This arrangement of the test line forms a shield. In this case, in order to spy out the circuit arrangement, it is necessary to manipulate the test line, for example by bridging the test line and removing the regions which have been bridged. An associated change in the propagation time is determined by comparing it with the predefined comparison value and indicates an attack. It goes without saying that interruptions in the test line are also detected using the test signal which has been passed onto the test line and can no longer be detected.

In one exemplary embodiment, the test line is part of an active shield. In this case, it is not only possible to provide the test signal for the purpose of determining the propagation time over the test line. Rather, further test signals are passed over the test line and detected, in particular during operation of the circuit arrangement. A difference between the signal which has been impressed and the signal which has been detected can be used to indicate an attack. Suitable test signals for such a refinement are, for example, random sequences or predefined bit patterns.

In one exemplary embodiment, the comparison unit is coupled to the clock signal generator in such a manner that the clock frequency is regulated to a reference clock frequency which results from the propagation time. Such regulation can be effected by virtue of the comparison unit providing a control signal which contains information relating to whether the instantaneous clock frequency is higher or lower than the predefined reference clock frequency.

One exemplary embodiment of the method for checking the clock frequency of a clock signal comprises transmitting a test signal over a test line, detecting a propagation time of the test signal, and checking whether the clock signal and the propagation time are in a predefined relationship.

The method detects whether the clock duration of the clock signal is a multiple of the propagation time, with the result that even high clock frequencies can be tested with a high level of accuracy. This can be effected by counting the number of clock pulses during the propagation time.

The test signal and its propagation time can be used to draw conclusions regarding whether the length of the test line has been manipulated or interrupted.

In one exemplary embodiment, the propagation time is used to control the clock frequency of the clock signal since it also contains information regarding whether the instantaneous clock signal frequency is above or below the predefined value.

The invention is explained below using exemplary embodiments and with reference to the drawing.

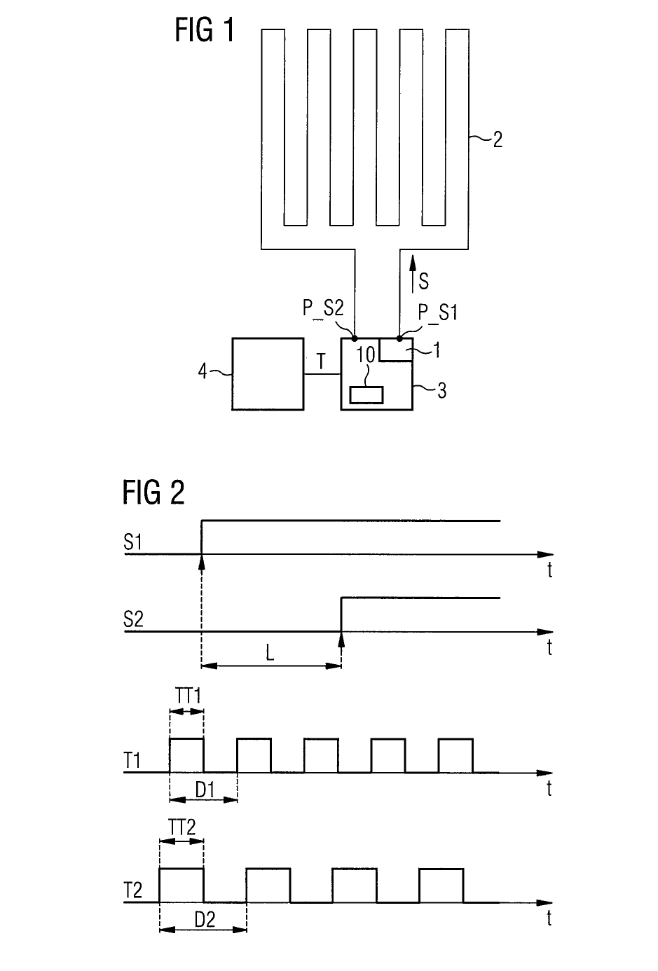

FIG. 1 shows a schematic circuit diagram of an integrated circuit arrangement for checking a clock signal T. The circuit arrangement comprises a test signal generator 1. This test signal generator 1 is coupled to a test line 2. Provision is also made of a comparison unit 3 which is coupled to the test signal generator 1 and to the test line 2.

The test signal generator 1 generates a test signal S which is passed onto the test line 2. On account of a finite propagation time of the test signal S over the test line 2, the test signal T is detected by the comparison unit 3 only after a finite time. The time difference between impressing the test signal S onto the start P_S1 of the test line 2 and detecting it at the end P_S2 of the test line 2 is referred to as the propagation time. The propagation time of the test signal S depends on the length of the test line 2.

The longer the test line 2, the longer the propagation time. The longer the propagation time, the less important measurement errors and system-inherent fluctuations in the propagation time. For this reason, the propagation time - as a reference signal —is as long as possible in one exemplary embodiment. This is associated with a long test line 2. Such a long test line 2 may be formed on an integrated circuit, for example, by the test line 2 running back and forth or in meandering fashion. This is indicated in FIG. 1.

Furthermore, a clock signal generator 4 which outputs a clock signal T that is supplied to the comparison unit 3 is provided in the circuit arrangement in FIG. 1.

The clock signal generator 4 not only provides the comparison unit 3 with the clock signal T but also a multiplicity of further circuit units inside the integrated circuit which have not been illustrated in FIG. 1. Internal operation and communication of the circuit units are effected using this internal clock T.

The extent to which the clock frequency of the clock signal T corresponds to a predefined clock frequency can be determined by comparing the clock signal T and the propagation time of the test signal S. This is explained below.

FIG. 2 shows exemplary relationships between the test signal S and the clock signal T.

The temporal profile of the test signal S at the start of the test line 2 is illustrated as the signal S1. This location is labeled with the reference symbol P_S1 in FIG. 1. For example, the test signal S is a pulse or a jump function since edges can be easily detected.

The temporal profile of the test signal S at the end of test line, which is detected by the comparison unit after it has passed through the test line 2, is illustrated as the signal S2. This location is labeled with the reference symbol P_S2 in FIG. 1. A time difference L between the edges of the signal S1 and those of the signal S2 results on account of the propagation time delay over the test line 2.

FIG. 2 also shows two exemplary clock signals T1 and T2 which differ in terms of their pulse duration TT1 and TT2 and their period D1 and D2. The pulse duration of the clock signal T is usually a great deal shorter than the propagation time L. This is only indicated in FIG. 2.

The comparison device 3 checks whether the clock signal T is in a given relationship with the propagation time L. This indicates whether the clock frequency of the clock signal T satisfies the predefined requirements or whether there is possibly an attack.

Different approaches are possible for checking. For example, a check can be carried out in order to determine whether a predefined number of pulses of the clock signal T is provided within the propagation time L. If fluctuations in the clock frequency are tolerated, a check can be carried out in order to determine whether the number of pulses is within predefined limits. The predefined comparison value or comparison value range is stored in a register 10.

Alternatively, particularly in the case of relatively small differences between the pulse duration and the propagation time, it is possible to determine whether a predefined, for example integer, multiple of the pulse duration is within the propagation time. This would be the case for the signal T1 by virtue of precisely two periods D1 being inside the propagation time L.

The period D2 is longer in the signal T2, with the result that it is not possible to detect two periods D2 inside the propagation time L.

In one exemplary embodiment, the number of clock pulses during the propagation time is measured indirectly. A reference signal which is supplied to an integrator, for example, is generated on the basis of the propagation time.

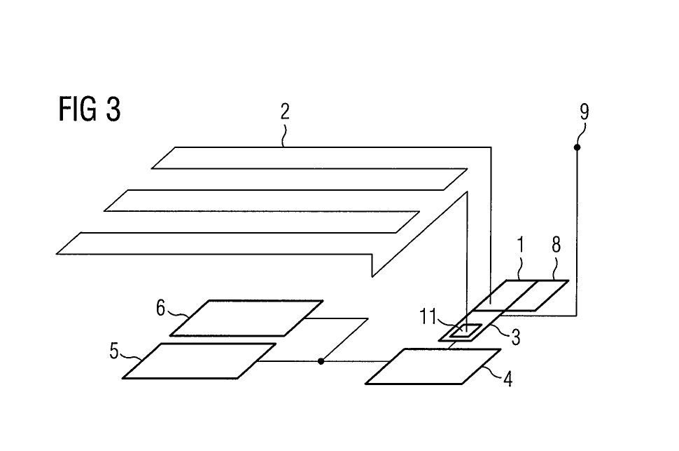

FIG. 3 shows a perspective illustration of a schematic circuit diagram of another exemplary embodiment of the circuit arrangement.

The same reference symbols indicate the same parts of the arrangement. In order to avoid repetition, corresponding arrangements are not described several times.

The circuit arrangement illustrated in FIG. 3 comprises two interconnect or metallization planes. It goes without saying that it is also conceivable for an integrated circuit arrangement to also comprise further planes. The test line 2 is arranged as a shield on the uppermost plane, so that regions of the test line 2 are close together and run back and forth and cover the circuit arrangement lying underneath. In the region protected by the shield, sections of the test line 2 run close together in order to protect the regions lying underneath. The shield effect is achieved using this arrangement.

In order to attack the circuit regions 5, 6 lying underneath, the test line 2 would have to be either severed or bridged. The former would be associated with a change in the propagation time L. The latter would make it impossible to detect the propagation time. In the first-mentioned case, a difference to the clock frequency detected is almost inevitably established since it is extremely difficult to manipulate the length of the test line 2 and the clock in a manner matched to one another. The difference between the propagation time L and the internal clock frequency indicates an attack.

In such a case, the circuit arrangement can be designed to carry out suitable countermeasures, for example restarting or carrying out suitable defensive actions, for example deleting registers.

In addition to the further circuit units 5, 6 which are arranged under the plane containing the test line 2, the circuit arrangement also comprises a signal generator 8. The signal generator 8 can be used to pass further signals, for example random sequences, over the test line 2. A difference between the signals which have been impressed and the signals which have been detected indicates an attack. An active shield is formed by means of this arrangement.

In one exemplary embodiment, an external clock is monitored using the test line 2. In this exemplary embodiment, a connection 9 for applying the external clock is coupled to the comparison device 3.

The exemplary embodiment of the comparison device 3 comprises a counter 11 whose gate time or opening time is predefined by the propagation time over the test line 2. The clock cycles of the applied clock signal T are added in the counter 11 during the propagation time L. If the counter 11 outputs an excessively high or excessively low number after the opening time has elapsed, an alarm is triggered, for example, or a register is set in order to indicate this event.

The result of the propagation time comparison can also be used to regulate the clock frequency of the clock signal T, which is provided by the clock signal generator 4, to the predefined clock frequency. In this case, the number of clock pulses is used as information regarding the extent to which the instantaneous clock frequency differs from the predefined clock frequency. The comparison unit can be designed to regulate the clock signal on the basis of this information or to provide a corresponding regulating device with the information as a regulating signal.

What is claimed is:

1. An integrated circuit arrangement comprising:
a test line;
a test signal generator which is coupled to the test line and is designed to pass a test signal onto the test line; and
a comparison unit comprising an input for applying a clock signal, the comparison unit being coupled to the test line and being designed to detect a propagation time of the test signal over the test line and to check whether the clock signal and the propagation time are in a predefined relationship.

2. The integrated circuit arrangement as claimed in claim 1, wherein the comparison unit is further designed to detect whether the propagation time is at least a predefined first multiple of the clock duration of the clock signal and is at most a predefined second multiple of the clock duration of the clock signal.

3. The integrated circuit arrangement as claimed in claim 1, wherein the comparison unit further comprises a counter which counts the number of clock pulses of the clock signal during the propagation time of the test signal.

4. The integrated circuit arrangement as claimed in claim 3, wherein the comparison unit is further designed to check whether the clock pulses counted match a comparison value or are within a predefined comparison value range.

5. The integrated circuit arrangement as claimed in claim 4, further comprising a register designed to provide the comparison value or the comparison value range for the comparison unit.

6. The integrated circuit arrangement as claimed in claim 1, wherein the test line is arranged such that it runs back and forth.

7. The integrated circuit arrangement as claimed in claim 1, wherein the test line is arranged in an upper conductor layer of the integrated circuit arrangement.

8. The integrated circuit arrangement as claimed in claim 1, wherein the test line is part of an active shield.

9. The integrated circuit arrangement as claimed in claim 1, further comprising a clock signal generator which generates the clock signal and is coupled to the comparison unit.

10. The integrated circuit arrangement as claimed in claim 9, wherein the clock frequency of the clock signal is regulated by the comparison unit.

11. The integrated circuit arrangement as claimed in claim 1, further comprising a connection designed to apply an external clock signal, said connection being coupled to the comparison unit.

12. An integrated circuit arrangement comprising:
a test line;
a test signal generator which is coupled to the test line and is designed to pass a test signal onto the test line; and
a comparison unit comprising an input for applying a clock signal, the comparison unit being coupled to the test line and being designed to detect a propagation time of the test signal over the test line and to check whether the propagation time is at least a predefined first multiple of the clock duration of the clock signal and is at most a predefined second multiple of the clock duration of the clock signal.

13. The integrated circuit arrangement as claimed in claim 12, wherein the comparison unit further comprises a counter which is designed to count the number of clock pulses of the clock signal during the propagation time of the test signal.

14. The integrated circuit arrangement as claimed in claim 13, wherein the comparison unit is further designed to check whether the clock pulses counted match a comparison value or are within a predefined comparison value range.

15. The integrated circuit arrangement as claimed in claim 14, further comprising a register designed to provide the comparison value or the comparison value range for the comparison unit.

16. The integrated circuit arrangement as claimed in claim 12, wherein the test line is arranged such that it runs back and forth.

17. The integrated circuit arrangement as claimed in claim 12, wherein the test line is arranged in an upper conductor layer of the integrated circuit arrangement.

18. The integrated circuit arrangement as claimed in claim 12, wherein the test line is in the form of an active shield.

19. The integrated circuit arrangement as claimed in claim 12, further comprising a clock signal generator which is coupled to the comparison unit and is designed to generate the clock signal.

20. The integrated circuit arrangement as claimed in claim 19, wherein the clock frequency of the clock signal is able to be regulated by the comparison unit.

21. The integrated circuit arrangement as claimed in claim 12, further comprising a connection designed to apply an external clock signal, said connection being coupled to the comparison unit.

22. A method for checking a clock signal frequency of a clock signal, said method comprising:
transmitting a test signal over a test line;
detecting a propagation time of the test signal; and
checking whether the clock signal and the propagation time are in a predefined relationship.

23. The method as claimed in claim 22, further comprising detecting whether the propagation time is at least a predefined first multiple of the clock duration of the clock signal and is at most a predefined second multiple of the clock duration of the clock signal.

24. The method as claimed in claim 22, further comprising counting the number of clock pulses during the propagation time.

25. The method as claimed in claim 24, further comprising checking whether the clock pulses counted match a comparison value or are within a predefined comparison value range.

26. The method as claimed in claim 22, further comprising regulating the clock frequency of the clock signal on the basis of the propagation time of the test signal.

27. A method for checking a clock signal frequency of a clock signal, said method comprising:
transmitting a test signal over a test line;
detecting a propagation time of the test signal; and
checking whether the propagation time is at least a predefined first multiple of the clock duration of the clock signal and is at most a predefined second multiple of the clock duration of the clock signal.

28. The method as claimed in claim 27, further comprising counting the number of clock pulses during the propagation time.

29. The method as claimed in claim 28, further comprising determining whether the clock pulses counted match a comparison value or are within a predefined comparison value range.

30. The method as claimed in claim 27, further comprising regulating the clock frequency of the clock signal on the basis of the propagation time of the test signal.

31. An integrated circuit arrangement for checking a clock signal frequency of a clock signal, said integrated circuit arrangement comprising:
a transmitting means for transmitting a test signal over a test line;
a detecting means for detecting a propagation time of the test signal; and
a checking means for checking whether the clock signal and the propagation time are in a predefined relationship.
